(19) United States
(12) Patent Application Publication
(10) Pub. No.: US 2017/0186634 A1
(43) Pub. Date: Jun. 29, 2017

(54) SUBSTRATE PROCESSING APPARATUS

(71) Applicant: HITACHI KOKUSAI ELECTRIC INC., Tokyo (JP)

(72) Inventors: Yoshihiko YANAGISAWA, Toyama-shi (JP); Masaaki UENO, Toyama-shi (JP); Naofumi OHASHI, Toyama-shi (JP)

(73) Assignee: HITACHI KOKUSAI ELECTRIC INC., Tokyo (JP)

(21) Appl. No.: 15/071,606

(22) Filed: Mar. 16, 2016

(30) Foreign Application Priority Data
Dec. 25, 2015 (JP) 2015-253778

(51) Int. Cl. H01L 21/67; H01L 21/02; C23C 16/46; H01L 21/687; H01J 37/32; C23C 16/455

(52) U.S. Cl. CPC H01L 21/67196; H01J 37/32009; H01J 37/3244; C23C 16/455; C23C 16/46; H01L 21/68785; H01L 21/68792; H01L 21/67098; H01L 21/67167; H01L 21/67207; H01L 21/02164; H01L 21/02211; H01L 21/02271; H01J 2237/334

(57) ABSTRACT

A substrate processing apparatus, including: a process chamber configured to process a substrate, a transfer chamber adjoining the process chamber, a shaft installed in the transfer chamber, a substrate mounting stand connected to the shaft and including a heating part, a first thermal insulation part installed in a wall of the transfer chamber at a side of the process chamber, and a second thermal insulation part installed in the shaft at a side of the substrate mounting stand.

### CROSS-REFERENCE TO RELATED APPLICATION(S)

This application is based upon and claims the benefit of priority from Japanese Patent Application No. 2015-253778, filed on Dec. 25, 2015, the entire contents of which are incorporated herein by reference.

### TECHNICAL FIELD

The present disclosure relates to a substrate processing apparatus.

### BACKGROUND

As one of processes of manufacturing a semiconductor apparatus (device), there has been performed a processing process in which a process gas and a reaction gas are supplied to a substrate to form a film on the substrate.

However, it is sometimes the case that the gas supply to a substrate becomes uneven and the processing uniformity decreases.

### SUMMARY

According to one embodiment of the present disclosure, there is provided a technique, including: a process chamber configured to process a substrate, a transfer chamber adjoining the process chamber, a shaft installed in the transfer chamber, a substrate mounting stand connected to the shaft and including a heating part, a first thermal insulation part installed in a wall of the transfer chamber at a side of the process chamber, and a second thermal insulation part installed in the shaft at a side of the substrate mounting stand.

### BRIEF DESCRIPTION OF THE DRAWINGS

FIG. 1 is a schematic horizontal sectional view of a substrate processing system according to one embodiment.

FIG. 2 is a schematic vertical sectional view of the substrate processing system according to one embodiment.

FIG. 3 is a schematic view of a vacuum transfer robot of the substrate processing system according to one embodiment.

FIG. 4 is a schematic configuration view of a substrate processing apparatus according to one embodiment.

FIG. 5 is a schematic vertical sectional view of a chamber according to one embodiment.

FIG. 6 is a view for explaining a gas supply system according to one embodiment.

FIG. 7 is a schematic configuration view of a controller of the substrate processing system according to one embodiment.

FIG. 8 is a flowchart of a substrate processing process according to one embodiment.

FIG. 9 is a sequence diagram of the substrate processing process according to one embodiment.

FIG. 10 is a schematic vertical sectional view of a chamber according to another embodiment.

FIGS. 11A to 11D illustrate modifications of a stress relaxation material.

### DETAILED DESCRIPTION

### First Embodiment

A first embodiment of the present disclosure will now be described with reference to the drawings. In a high temperature process, heat generated from a susceptor or a reaction chamber is transferred to the lower side of the reaction chamber (a transfer space or a transfer chamber), thereby increasing the temperature thereof. Thus, it is typical that the temperature of the transfer chamber is set at a required temperature or less by supplying cooling water. However, due to the structure of an apparatus, a hard-to-cool portion may exist. The transfer chamber may be heated and expanded. The position of a substrate mounting stand (in XYZ directions) may be shifted and, consequently, the position of a gas supply part with respect to a substrate may be shifted. This may pose a problem in that the substrate processing uniformity decreases. It is an object of the present disclosure to provide a technique capable of suppressing the expansion of the transfer chamber attributable to the heat mentioned above.

Hereinafter, a substrate processing system according to one embodiment will be described.

(1) Configuration of Substrate Processing System

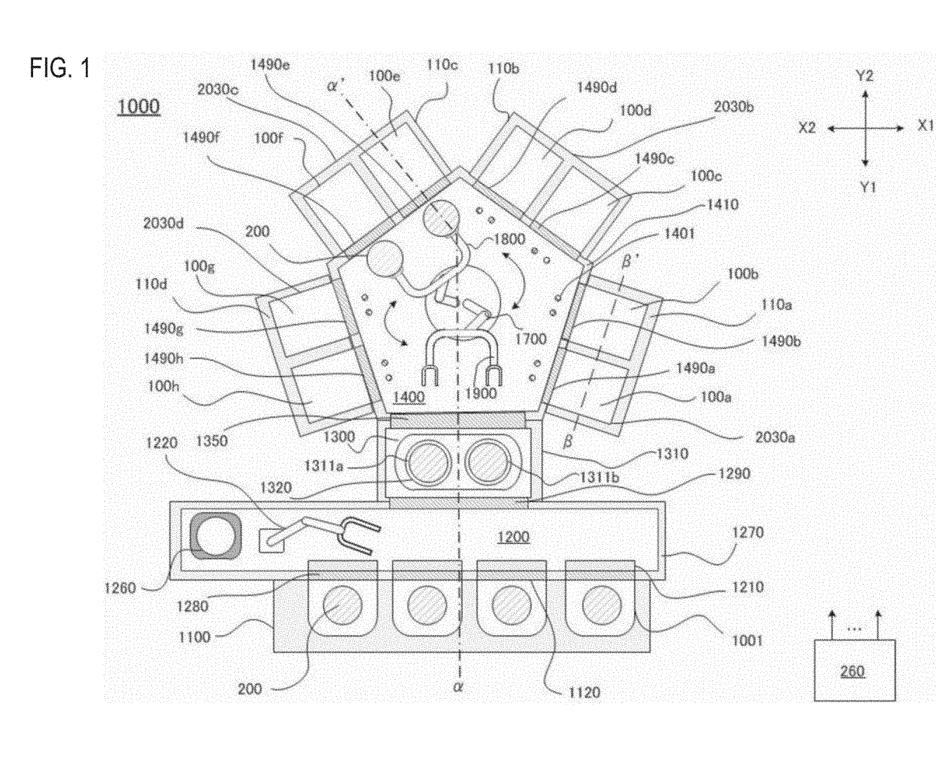

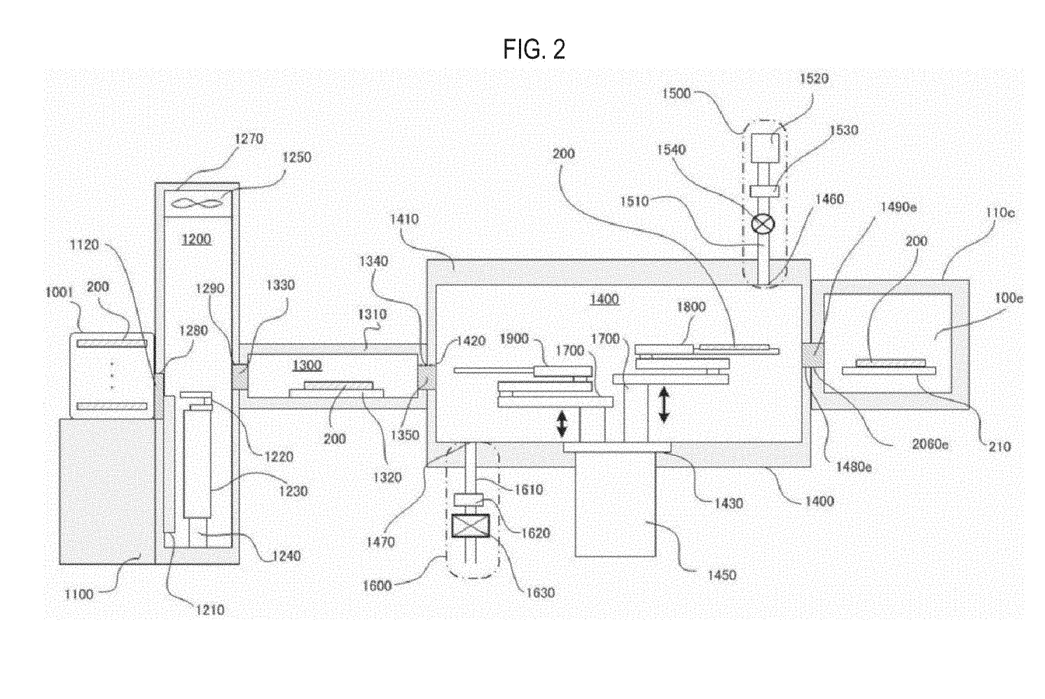

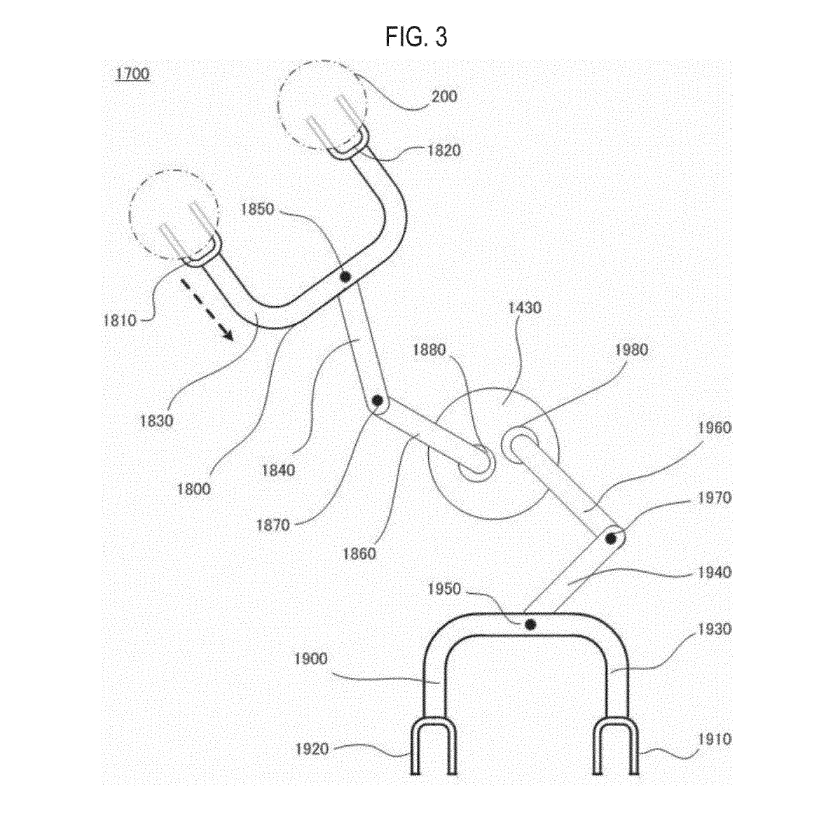

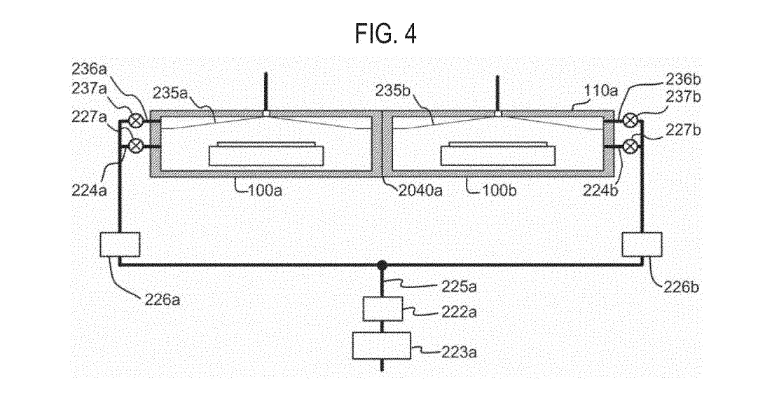

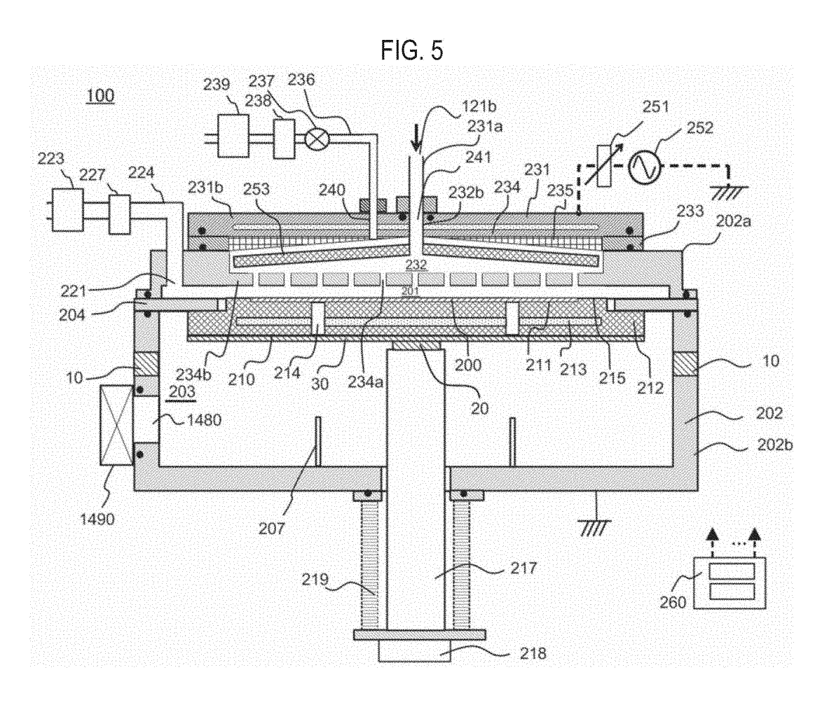

A schematic configuration of a substrate processing system according to one embodiment of the present disclosure will be described with reference to FIGS. 1 to 5. FIG. 1 is a horizontal sectional view of a substrate processing system according to one embodiment. FIG. 2 is a vertical sectional view taken along a line α-α′ in FIG. 1, illustrating a configuration of the substrate processing system according to the present embodiment. FIG. 3 is an explanatory view illustrating details of an arm shown in FIG. 1. FIG. 4 is a vertical sectional view taken along a line β-β′ in FIG. 1, illustrating a gas supply system which supplies a gas to a process module. FIG. 5 is an explanatory view illustrating a chamber installed in a process module.

Referring to FIGS. 1 and 2, a substrate processing system 1000, to which the present disclosure is applied, is configured to process wafers 200. The substrate processing system 1000 is mainly configured by an I/O stage 1100, an atmosphere transfer chamber 1200, a load lock chamber 1300, a vacuum transfer chamber 1400 and process modules 110. Next, the respective configurations will be described in detail. In the descriptions made with reference to FIG. 1, it is assumed that an X1 direction is the right side, an X2 direction is the left side, an Y1 direction is the front side, and an Y2 direction is the rear side.

(Atmosphere Transfer Chamber and I/O Stage)

The I/O stage (load port) 1100 is installed at the front side of the substrate processing system 1000. A plurality of pods 1001 are mounted on the I/O stage 1100. The pods 1001 are used as carriers which carry substrates 200 such as silicon (Si) substrates or the like. Unprocessed substrates (wafers) 200 or processed substrates 200 are stored, respectively in a horizontal posture within the pods 1001.

A cap 1120 is installed in each of the pods 1001 and is opened or closed by a pod opener 1210 which will be described later. The pod opener 1210 opens or closes the cap 1120 of each of the pods 1001 held on the I/O stage 1100 and opens or closes a substrate loading/unloading opening of each of the pods 1001, thereby enabling the substrates 200 to be loaded into or unloaded from each of the pods 1001. The pods 1001 are supplied to and discharged from the I/O stage 1100 by an in-process transfer device (RGV), which is not shown in the figures.

The I/O stage 1100 is adjacent to the atmosphere transfer chamber 1200. The load lock chamber 1300 to be described later is connected to the opposite surface of the atmosphere transfer chamber 1200 from the I/O stage 1100.

An atmosphere transfer robot 1220 as a first transfer robot configured to transfer the substrates 200 is installed within the atmosphere transfer chamber 1200. As illustrated in FIG. 2, the atmosphere transfer robot 1220 is configured to move up and down by an elevator 1230 installed in the atmosphere transfer chamber 1200 and is also configured to move linearly in a left-right direction by a linear actuator 1240.

As illustrated in FIG. 2, a clean unit 1250 configured to supply clean air is installed in the upper portion of the atmosphere transfer chamber 1200. Furthermore, as illustrated in FIG. 1, a device (hereinafter referred to as a pre-aligner) 1260 configured to align a notch or an orientation flat formed in each of the substrates 200 is installed at the left side of the atmosphere transfer chamber 1200.

As illustrated in FIGS. 1 and 2, substrate loading/unloading gates 1280, through which the substrates 200 are loaded into and unloaded from the atmosphere transfer chamber 1200, and pod openers 1210 are installed on the front surface of a housing 1270 of the atmosphere transfer chamber 1200. The I/O stage (load port) 1100 is installed at the opposite side of the substrate loading/unloading gates 1280 from the pod openers 1210, namely at the outer side of the housing 1270.

A substrate loading/unloading gate 1290, through which the wafers 200 are loaded into or unloaded from the load lock chamber 1300, is installed on the rear surface of the housing 1270 of the atmosphere transfer chamber 1200. The substrate loading/unloading gate 1290 is opened and closed by a gate valve 1330 to be described later, thereby enabling the loading and unloading of the wafers 200.

(Load Lock (L/L) Chamber)

The load lock chamber 1300 is adjacent to the atmosphere transfer chamber 1200. The vacuum transfer chamber 1400 to be described later is disposed on the opposite surface of a housing 1310 of the load lock chamber 1300 from the atmosphere transfer chamber 1200. Since the internal pressure of the housing 1310 fluctuates depending on the pressure of the atmosphere transfer chamber 1200 and the pressure of the vacuum transfer chamber 1400, the load lock chamber 1300 is configured to have a structure capable of withstanding a negative pressure.

A substrate loading/unloading gate 1340 is installed on the surface of the housing 1310 that adjoins the vacuum transfer chamber 1400. The substrate loading/unloading gate 1340 is opened and closed by a gate valve 1350, thereby enabling the loading and unloading of the wafers 200.

A substrate mounting stand 1320 having at least two substrate mounting surfaces 1311 (1311a and 1311b) for holding the wafers 200 is installed within the load lock chamber 1300. The distance between the substrate mounting surfaces 1311 is set depending on the distance between fingers of a vacuum transfer robot 1700 which will be described later.

(Vacuum Transfer Chamber)

The substrate processing system 1000 includes a vacuum transfer chamber 1400 (transfer module) as a transfer chamber which serves as a transfer space in which the substrates 200 are transferred under a negative pressure. A housing 1410 which constitutes the vacuum transfer chamber 1400 is formed in a pentagonal shape in a plane view. The load lock chamber 1300 and process modules 110a to 110d configured to process the wafers 200 are connected to the respective sides of the pentagonal housing 1410. A vacuum transfer robot 1700 as a second transfer robot configured to transfer the substrates 200 under a negative pressure is installed in substantially a central portion of the vacuum transfer chamber 1400 using a flange 1430 as a base. In the present embodiment, there is illustrated an example where the vacuum transfer chamber 1400 has a pentagonal shape. However, the vacuum transfer chamber 1400 may have other polygonal shapes such as a square shape or a hexagonal shape.

A substrate loading/unloading gate 1420 is installed in a sidewall of the housing 1410 which adjoins the load lock chamber 1300. The substrate loading/unloading gate 1420 is opened and closed by a gate valve 1350, thereby enabling the loading and unloading of the wafers 200.

As illustrated in FIG. 2, the vacuum transfer robot 1700 installed within the vacuum transfer chamber 1400 is configured to be moved up and down by an elevator 1450 while maintaining the air-tightness of the vacuum transfer chamber 1400 with the flange 1430. The detailed configuration of the vacuum transfer robot 1700 will be described later. The elevator 1450 is configured to independently move up and down two arms 1800 and 1900 of the vacuum transfer robot 1700.

An inert gas supply hole 1460 for supplying an inert gas into the housing 1410 is formed in a ceiling of the housing 1410. An inert gas supply pipe 1510 is installed in the inert gas supply hole 1460. An inert gas source 1520, a mass flow controller 1530 and a valve 1540 are installed in the inert gas supply pipe 1510 sequentially from the upstream side so as to control a supply amount of an inert gas supplied into the housing 1410.

An inert gas supply part 1500 of the vacuum transfer chamber 1400 is mainly configured by the inert gas supply pipe 1510, the mass flow controller 1530 and the valve 1540. Furthermore, the inert gas source 1520 and the inert gas supply hole 1460 may be included in the inert gas supply part 1500.

An exhaust hole 1470 for exhausting an atmosphere of the housing 1410 is formed in a bottom wall of the housing 1410. An exhaust pipe 1610 is installed in the exhaust hole 1470. An auto pressure controller (APC) 1620 as a pressure controller and a pump 1630 are installed in the exhaust pipe 1610 sequentially from the upstream side.

A gas exhaust part 1600 of the vacuum transfer chamber 1400 is mainly configured by the exhaust pipe 1610 and the APC 1620. Furthermore, the pump 1630 and the exhaust hole 1470 may be included in the gas exhaust part.

The atmosphere of the vacuum transfer chamber 1400 is controlled by the cooperation of the inert gas supply part 1500 and the gas exhaust part 1600. For example, the internal pressure of the housing 1410 is controlled.

As illustrated in FIG. 1, the process modules 110a, 110b, 110c and 110d configured to perform a desired process with respect to the wafers 200 are connected to the sidewalls in which the load lock chamber 1300 is not installed, of five sidewalls.

Chambers 100, which are one configuration of the substrate processing apparatus, are installed in the respective process modules 110a, 110b, 110c and 110d. Specifically, chambers 100a and 100b are installed in the process module 110a. Chambers 100c and 100d are installed in the process module 110b. Chambers 100e and 100f are installed in the process module 110c. Chambers 100g and 100h are installed in the process module 110d.

Substrate loading/unloading gates 1480 are installed in the sidewalls of the housing 1410 facing the respective chambers 100. For example, as illustrated in FIG. 2, a substrate loading/unloading gate 1480e is installed in the wall facing the chamber 100e.

In FIG. 2, if the chamber 100e is replaced by the chamber 100a, a substrate loading/unloading gate 1480a is installed in the wall facing the chamber 100a.

Similarly, if the chamber 100f is replaced by the chamber 100b, a substrate loading/unloading gate 1480b is installed in the wall facing the chamber 100b.

As illustrated in FIG. 1, gate valves 1490 are installed in the respective process chambers. Specifically, a gate valve 1490a is installed between the chamber 100a and the vacuum transfer chamber 1400. A gate valve 1490b is installed between the chamber 100b and the vacuum transfer chamber 1400. A gate valve 1490c is installed between the chamber 100c and the vacuum transfer chamber 1400. A gate valve 1490d is installed between the chamber 100c and the vacuum transfer chamber 1400. A gate valve 1490e is installed between the chamber 100e and the vacuum transfer chamber 1400. A gate valve 1490f is installed between the chamber 100f and the vacuum transfer chamber 1400. A gate valve 1490g is installed between the chamber 100g and the vacuum transfer chamber 1400. A gate valve 1490h is installed between the chamber 100h and the vacuum transfer chamber 1400.

The substrate loading/unloading gates 1480 are opened and closed by the respective gate valves 1490, thereby enabling the loading and unloading of the wafers 200 through the substrate loading/unloading gates 1480.

Subsequently, the vacuum transfer robot 1700 mounted in the vacuum transfer chamber 1400 will be described with reference to FIG. 3. FIG. 3 is an enlarged view of the vacuum transfer robot 1700 illustrated in FIG. 1.

The vacuum transfer robot 1700 includes two arms 1800 and 1900. The arm 1800 includes a fork portion 1830, at the distal ends of which, two end effectors 1810 and 1820 are installed. A middle portion 1840 is connected to the base of the fork portion 1830 via a shaft 1850.

The wafers 200 unloaded from each of the process modules 110 are held in the end effectors 1810 and 1820. In FIG. 2, there is illustrated an example where the wafers 200 unloaded from the process module 100c are held.

A bottom portion 1860 is connected to the middle portion 1840 via a shaft 1870 at a point of the middle portion 1840 existing far from the fork portion 1830. The bottom portion 1860 is disposed in the flange 1430 via a shaft 1880.

The arm 1900 includes a fork portion 1930, at the distal ends of which, two end effectors 1910 and 1920 are installed. A middle portion 1940 is connected to the base of the fork portion 1930 via a shaft 1950.

The wafers 200 unloaded from each of the load lock chamber 1300 are held in the end effectors 1910 and 1920.

A bottom portion 1960 is connected to the middle portion 1940 via a shaft 1970 at a point of the middle portion 1940 existing far from the fork portion 1930. The bottom portion 1960 is disposed in the flange 1430 via a shaft 1980.

The end effectors 1810 and 1820 are disposed in a higher position than the end effectors 1910 and 1920.

The vacuum transfer robot 1700 is capable of rotating about an axis and allowing the arms to be stretched.

(Process Module)

Subsequently, the process module 110a among the respective process modules 110 will be described with reference to FIGS. 1, 2 and 4. FIG. 4 is an explanatory view illustrating the relationship between the process module 110a, the gas supply part connected to the process module 110a and the gas exhaust part connected to the process module 110a.

In the present embodiment, there is illustrated the process module 110a. The remaining process modules 110b, 110c and 110d are identical in structure with the process module 110a and, therefore, will not be described herein.

As illustrated in FIG. 4, the chambers 100a and 100b, which are one configuration of the substrate processing apparatus for processing the wafer 200, are installed in the process module 110a. A partition wall 2040a is installed between the chambers 100a and 100b so that the internal atmospheres of the respective chambers are not mixed with each other.

As illustrated in FIG. 2, a substrate loading/unloading gate 2060e is installed in the wall where the chamber 100e and the vacuum transfer chamber 1400 adjoin each other. Similarly, a substrate loading/unloading gate 2060a is installed in the wall where the chamber 100a and the vacuum transfer chamber 1400 adjoin each other.

A substrate support part 210 configured to support the wafer 200 is installed in each of the chambers 100.

Gas supply parts configured to supply gases to the chambers 100a and 100b are connected to the process module 110a. The gas supply parts include a first gas supply part (process gas supply part), a second gas supply part (reaction gas supply part), a third gas supply part (first purge gas supply part), and a fourth gas supply part (second purge gas supply part). Configurations of the respective gas supply parts will be described.

(1) Configuration of Substrate Processing Apparatus

Descriptions will be made on a substrate processing apparatus according to a first embodiment.

A substrate processing apparatus 100 according to the present embodiment will be described. The substrate processing apparatus 100 is a unit for forming an insulation film having a high dielectric constant. As illustrated in FIG. 1, the substrate processing apparatus 100 is configured as a single-substrate-type substrate processing apparatus. One of processes of manufacturing a semiconductor device is performed in the substrate processing apparatus 100.

As illustrated in FIG. 5, the substrate processing apparatus 100 includes a process vessel 202. The process vessel 202 is configured as, e.g., a flat airtight vessel having a circular horizontal cross-section. Furthermore, the process vessel 202 is made of a metallic material such as, e.g., aluminum (Al) or stainless steel (SUS), or quartz. A process space (process chamber) 201, in which a wafer 200 such as a silicon wafer as a substrate is processed, and a transfer space (transfer chamber) 203 are formed within the process vessel 202. The process vessel 202 is configured by an upper vessel 202a and a lower vessel 202b. A partition plate 204 is installed between the upper vessel 202a and the lower vessel 202b. A space surrounded by the upper vessel 202a and positioned above the partition plate 204 will be referred to as a process space (process chamber) 201. A space surrounded by the lower vessel 202b and positioned below the partition plate 204 will be referred to as a transfer space 203.

A substrate loading/unloading gate 1480 adjoining a gate valve 1490 is formed on a side surface of the lower vessel 202b. The wafer 200 moves into and out of a transfer chamber (not shown) through the substrate loading/unloading gate 1480. A plurality of lift pins 207 are installed in a bottom portion of the lower vessel 202b. In addition, the lower vessel 202b is grounded.

In this regard, the thermal expansion coefficient of quartz, which is a constituent material of the upper vessel 202a, is 6×10⁻⁷/° C. When a temperature difference ΔT between a low temperature and a high temperature is equal to 300 degrees C., the upper vessel 202a may expand about 0.05 mm to about 0.4 mm. In the case where the constituent material of the lower vessel 202b is aluminum, thermal expansion coefficient of aluminum is 23×10⁻⁶/° C. When a temperature difference ΔT between a low temperature and a high temperature is equal to 300 degrees C., the lower vessel 202b may expand about 2.0 mm to about 14 mm. The expanded length ΔL is calculated by an equation ΔL=L×α×ΔT. In this equation, L is the length of a material [mm], α is the thermal expansion coefficient [/° C.], and ΔT is the temperature difference [° C.].

As described above, the expanded length (change amount) varies depending on the material. Due to the difference in the change amount, there is a problem in that the center positions (XY direction positions) of a substrate mounting stand 212 and a shower head 234 are deviated from each other and the processing uniformity is reduced. Furthermore, due to the difference in the expanded length (change amount) in the Z direction, the distance between a mounting surface 211 and a dispersion plate 234b is changed and the exhaust conductance within a process chamber 201 or the exhaust conductance from the process chamber 201 to the exhaust hole 221 is changed. This poses a problem in that the processing uniformity is reduced. Moreover, the distance between the center position of the transfer chamber 1400 and the center position of the process module 110a grows larger. This poses a problem in that the wafer 200 cannot be transferred to the center of the mounting surface 211. In addition, the distance between the center position of the chamber 100a and the center position of the chamber 100b grows larger. This poses a problem in that the wafer 200 cannot be transferred to the center of the mounting surface 211.

Thus, in the present embodiment, a first thermal insulation part 10 is installed on the side surface of the lower vessel 202b in an upper position than the gate valve 1490. The first thermal insulation part 10 is installed under a below-mentioned second thermal insulation part in the Z direction (height direction). By installing the first thermal insulation part 10, it is possible to suppress expansion of the lower vessel 202b in the XY direction and the Z direction, thereby solving the aforementioned problems. While the process module 110a is described herein, the above descriptions are equally applicable to other process modules 110b, 110c and 110d.

The first thermal insulation part 10 is made of, for example, one of a heat-resistant resin, a dielectric resin, quartz and graphite or a composite material having low heat conductivity and is formed in a ring shape.

A substrate support part 210 configured to support the wafer 200 is installed within the process chamber 201. The substrate support part 210 includes a mounting surface 211 configured to hold the wafer 200 and a substrate mounting stand 212 having the mounting surface 211 and an outer peripheral surface 215 on the front surface of the substrate mounting stand 212. A heater 213 as a heating part may be installed in the substrate mounting stand 212. By installing the heating part, it is possible to heat the substrate and to improve the quality of a film formed on the substrate. In the substrate mounting stand 212, through-holes 214, which the lift pins 207 penetrate, may be respectively formed in the positions corresponding to the lift pins 207. Furthermore, the height of the mounting surface 211 formed on the front surface of the substrate mounting stand 212 may be set smaller than the height of the outer peripheral surface 215 by the length corresponding to the thickness of the wafer 200. By employing this configuration, the difference between the height of the upper surface of the wafer 200 and the height of the outer peripheral surface 215 of the substrate mounting stand 212 becomes small. This makes it possible to suppress the generation of a turbulent flow of a gas attributable to the height difference. In the case where the turbulent flow of a gas does not affect the processing uniformity of the wafer 200, the height of the outer peripheral surface 215 may be set to become equal to or larger than the height of the mounting surface 211.

The substrate mounting stand 212 is supported by a shaft 217. The shaft 217 extends through the bottom portion of the process vessel 202. Furthermore, the shaft 217 is connected to an elevator mechanism 218 outside the process vessel 202. By moving up and down the shaft 217 and the substrate mounting stand 212 through the operation of the elevator mechanism 218, it is possible to move up and down the wafer 200 held on the mounting surface 211. The periphery of a lower end portion of the shaft 217 is covered with a bellows 219. The interior of the processor 201 is kept air-tight. A second thermal insulation part 20 is installed between the shaft 217 and the substrate mounting stand 212. The second thermal insulation part 20 serves to restrain the heat generated in the heater 213 from being transferred to the shaft 217 or the transfer space 203. The second thermal insulation part 20 may be installed higher than the gate valve 1490. Further, the diameter of the second thermal insulation part 20 may be set smaller than the diameter of the shaft 217. This makes it possible to suppress heat transfer from the heater 213 to the shaft 217 and to improve the temperature uniformity of the substrate mounting stand 212. In addition, a reflection part 30 configured to reflect the heat coming from the heater 213 is installed under the substrate mounting stand 212 and between the substrate mounting stand 212 and the second thermal insulation part 20, namely under the heater 213 and above the second thermal insulation part 20.

By installing the reflection part 30 above the second thermal insulation part 20, it is possible to reflect the heat radiated from the heater 213 without radiating the heat toward the inner wall of the lower vessel 202b. Furthermore, it is possible to improve the reflection efficiency and to improve the efficiency of heating the substrate 200 with the heater 213. In a case where the reflection part 30 is installed under the second thermal insulation part 20, the heat irradiated from the heater 213 is absorbed by the second thermal insulation part 20. Thus, the amount of heat reflected toward the heater 213 is reduced and the heating efficiency of the heater 213 is reduced. Furthermore, it is possible to restrain the second thermal insulation part 20 from being heated and to restrain the shaft 217 from being heated by the second thermal insulation part 20.

When transferring the wafer 200, the substrate mounting stand 212 is moved down such that the mounting surface 211 is located in a position of the substrate loading/unloading gate 206 (or a wafer transfer position). When processing the wafer 200, as shown in FIG. 1, the substrate mounting stand 212 is moved up until the wafer 200 reaches a processing position (or a wafer processing position) within the process chamber 201.

Specifically, when the substrate mounting stand 212 is moved down to the wafer transfer position, the upper end portions of the lift pins 207 protrude from an upper surface of the mounting surface 211 so that the lift pins 207 support the wafer 200 from below. Further, when the substrate mounting stand 212 is moved up to the wafer processing position, the lift pins 207 are retracted from the upper surface of the mounting surface 211 so that the mounting surface 211 supports the wafer 200 from below. Moreover, the lift pins 207 may be made of a material such as, e.g., quartz, alumina or the like, because the lift pins 207 make direct contact with the wafer 200. In addition, an elevator mechanism may be installed in the lift pins 207 so that the substrate mounting stand 212 and the lift pins 207 can move relative to each other. In the processing position, the first thermal insulation part 10 is installed higher than the gate valve 1490 and lower than the second thermal insulation part 20.

By installing the second thermal insulation part 20 higher than the first thermal insulation part 10, it is possible to reduce the amount of heat radiated from the shaft 217 toward the inner wall of the lower vessel 202b. Furthermore, even when the heat is radiated from the shaft 217, it is possible to restrain the heat received by the inner wall of the lower vessel 202b facing the shaft 217 from being transferred to the gate valve 1490.

Furthermore, it may be possible to employ a configuration in which the first thermal insulation part 10 is installed in the vicinity of the exhaust hole 221 which will be described later. With this configuration, it is possible to restrain various portions from being heated via the wall constituting the process vessel 202 or the transfer space 203 when thermal insulation is not performed near the exhaust hole 221 toward which a hot gas flows.

(Exhaust System)

An exhaust hole 221 as a first exhaust part configured to exhaust an atmosphere of the process chamber 201 is formed on an upper surface of an inner wall of the process chamber 201 (the upper vessel 202a). An exhaust pipe 224 as a first exhaust pipe is connected to the exhaust hole 221. A pressure regulator 222a, such as an auto pressure controller (APC) or the like, for controlling the internal pressure of the process chamber 201 at a predetermined pressure, and a vacuum pump 223 are sequentially and serially connected to the exhaust pipe 224. A first exhaust part (exhaust line) is mainly configured by the exhaust hole 221, the exhaust pipe 224 and the pressure regulator 222a. Furthermore, the vacuum pump 223 may be included in the first exhaust part.

A shower head exhaust hole 240 as a second exhaust part configured to exhaust an atmosphere of a buffer chamber 232 is formed on an upper surface of an inner wall of the buffer space 232 above a shower head 234. An exhaust pipe 236 as a second exhaust pipe is connected to the shower head exhaust hole 240. A valve 237, a pressure regulator 238, such as an auto pressure controller (APC) or the like, for controlling the internal pressure of the buffer space 232 at a predetermined pressure, and a vacuum pump 239 are sequentially and serially connected to the exhaust pipe 236. A second exhaust part (exhaust line) is mainly configured by the shower head exhaust hole 240, the valve 237, the exhaust pipe 236 and the pressure regulator 238. Furthermore, the vacuum pump 239 may be included in the second exhaust part. Instead of installing the vacuum pump 239, the exhaust pipe 236 may be connected to the vacuum pump 223.

(Gas Introduction Hole)

A gas introduction hole 241 for supplying various kinds of gases into the process chamber 201 is formed on an upper surface (ceiling wall) of the shower head 234 installed in the upper portion of the process chamber 201. A configuration of a gas supply unit connected to the gas introduction hole 241 as a gas supply part will be described later.

(Gas Dispersion Part)

The shower head 234 is configured by a buffer chamber (space) 232, a dispersion plate 234b and dispersion holes 234a. The shower head 234 is installed between the gas introduction hole 241 and the process chamber 201. The gas introduced from the gas introduction hole 241 is supplied to the buffer space 232 (dispersion part) of the shower head 234. The shower head 234 is made of a material such as, e.g., quartz, alumina, stainless steel or aluminum.

Furthermore, a lid 231 of the shower head 234 may be made of an electrically conductive metal so as to serve as an activation part (excitation part) for exciting the gas existing within the buffer space 232 or the process chamber 201. In this case, an insulation block 233 is installed between the lid 231 and the upper vessel 202a to provide insulation between the lid 231 and the upper vessel 202a. A matcher 251 and a high-frequency power source 252 may be connected to the electrode (the lid 231) serving as an activation part so that electromagnetic waves (high-frequency power or microwaves) can be supplied to the electrode (the lid 231).

A dispersion plate 253 for diffusing the gas introduced from the gas introduction hole 241 into the buffer space 232 is installed in the buffer space 232.

(Process Gas Supply Part)

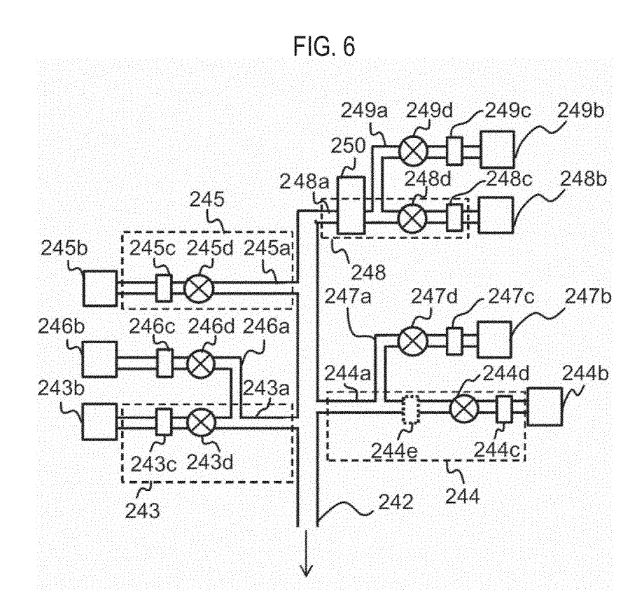

A common gas supply pipe 242 is connected to the gas introduction hole 241 connected to the dispersion plate 253. As illustrated in FIG. 6, a first gas supply pipe 243a, a second gas supply pipe 244a, a third gas supply pipe 245a and a cleaning gas supply pipe 248a are connected to the common gas supply pipe 242.

A first-element-containing gas (first process gas) is mainly supplied from a first gas supply part 243 including the first gas supply pipe 243a. A second-element-containing gas (second process gas) is mainly supplied from a second gas supply part 244 including the second gas supply pipe 244a. A purge gas is mainly supplied from a third gas supply part 245 including the third gas supply pipe 245a. A cleaning gas is supplied from a cleaning gas supply part 248 including the cleaning gas supply pipe 248a. A process gas supply part for supplying a process gas is configured by one or both of a first process gas supply part and a second process gas supply part. The process gas is configured by one or both of a first process gas and a second process gas.

(First Gas Supply Part)

A first gas supply source 243b, a mass flow controller (MFC) 243c, which is a flow rate controller (flow rate control part), and a valve 243d, which is an opening/closing valve, are installed in the first gas supply pipe 243a sequentially from the upstream side.

A gas containing a first element (a first process gas) is supplied from the first gas supply source 243b and is supplied to the buffer space 232 via the mass flow controller 243c, the valve 243d, the first gas supply pipe 243a and the common gas supply pipe 242.

The first process gas is one of precursor gases, namely one of process gases. In this regard, the first element is, for example, silicon (Si). That is to say, the first process gas is, for example, a silicon-containing gas. As the silicon-containing gas, it may be possible to use, for example, a dichlorosilane (SiH₂Cl₂): DCS) gas. A precursor of the first process gas may be any one of solid, liquid and gas under a room temperature and an atmospheric pressure. If the precursor of the first process gas is liquid under a room temperature and an atmospheric pressure, a vaporizer, which is not shown, may be installed between the first gas supply source 243b and the mass flow controller 243c. In the present embodiment, the precursor will be described as being a gas.

A downstream end of a first inert gas supply pipe 246a is connected to the first gas supply pipe 243a at the downstream side than the valve 243d. An inert gas supply source 246b, a mass flow controller (MFC) 246c, which is a flow rate controller (flow rate control part), and a valve 246d, which is an opening/closing valve, are installed in the first inert gas supply pipe 246a sequentially from the upstream side.

In this regard, the inert gas is, for example, a nitrogen (N₂) gas. As the inert gas, in addition to the N₂ gas, it may be possible to use a rare gas such as, e.g., a helium (He) gas, a neon (Ne) gas or an argon (Ar) gas.

A first-element-containing gas supply part 243 (also referred to as a silicon-containing gas supply part) is mainly configured by the first gas supply pipe 243a, the mass flow controller 243c and the valve 243d.

Furthermore, a first inert gas supply part is mainly configured by the first inert gas supply pipe 246a, the mass flow controller 246c and the valve 246d. Furthermore, the inert gas supply source 246b and the first gas supply pipe 243a may be included in the first inert gas supply part.

In addition, the first gas supply source 243b and the first inert gas supply part may be included in the first-element-containing gas supply part.

(Second Gas Supply Part)

A second gas supply source 244b, a mass flow controller (MFC) 244c, which is a flow rate controller (flow rate control part), and a valve 244d, which is an opening/closing valve, are installed in the upstream of the second gas supply pipe 244a sequentially from the upstream side.

A gas containing a second element (hereinafter referred to as a “second process gas”) is supplied from the second gas supply source 244b and is supplied to the buffer space 232 via the mass flow controller 244c, the valve 244d, the second gas supply pipe 244a and the common gas supply pipe 242.

The second process gas is one of process gases. Furthermore, the second process gas may be considered as a reaction gas or a modifying gas.

In this regard, the second process gas contains a second element differing from the first element. The second element includes, for example, one or more of oxygen (O), nitrogen (N), carbon (C) and hydrogen (H). In the present embodiment, the second process gas may be, for example, a nitrogen-containing gas. Specifically, an ammonia (NH₃) gas is used as the nitrogen-containing gas.

A second process gas supply part 244 is mainly configured by the second gas supply pipe 244a, the mass flow controller 244c and the valve 244d.

In addition, a remote plasma unit (RPU) 244e as an activation part may be installed to activate the second process gas.

A downstream end of the second inert gas supply pipe 247a is connected to the second gas supply pipe 244a at the downstream side than the valve 244d. An inert gas supply source 247b, a mass flow controller (MFC) 247c, which is a flow rate controller (flow rate control part), and a valve 247d, which is an opening/closing valve, are installed in the second inert gas supply pipe 247a sequentially from the upstream side.

An inert gas is supplied from the inert gas supply source 247b to the buffer space 232 via the mass flow controller 247c, the valve 247d and the second inert gas supply pipe 247a. The inert gas acts as a carrier gas or a dilution gas at a thin film forming process (S203 to S207, which will be described later).

A second inert gas supply part is mainly configured by the second inert gas supply pipe 247a, the mass flow controller 247c and the valve 247d. Furthermore, the inert gas supply source 247b and the second gas supply pipe 244a may be included in the second inert gas supply part.

In addition, the second gas supply source 244b and the second inert gas supply part may be included in the second-element-containing gas supply part 244.

(Third Gas Supply Part)

A third gas supply source 245b, a mass flow controller (MFC) 245c, which is a flow rate controller (flow rate control part), and a valve 245d, which is an opening/closing valve, are installed in the third gas supply pipe 245a sequentially from the upstream side.

An inert gas as a purge gas is supplied from the third gas supply source 245b and is supplied to the buffer space 232 via the mass flow controller 245c, the valve 245d, the third gas supply pipe 245a and the common gas supply pipe 242.

In this regard, the inert gas is, for example, a nitrogen (N₂) gas. As the inert gas, in addition to the N₂ gas, it may be possible to use a rare gas such as, e.g., a helium (He) gas, a neon (Ne) gas or an argon (Ar) gas.

A third gas supply part 245 (also referred to as a purge gas supply part) is mainly configured by the third gas supply pipe 245a, the mass flow controller 245c and the valve 245d.

(Cleaning Gas Supply Part)

A cleaning gas source 248b, a mass flow controller (MFC) 248c, a valve 248d and a remote plasma unit (RPU) 250 are installed in the cleaning gas supply pipe 248a sequentially from the upstream side.

A cleaning gas is supplied from the cleaning gas source 248b and is supplied to the buffer space 232 via the MFC 248c, the valve 248d, the RPU 250, the cleaning gas supply pipe 248a and the common gas supply pipe 242.

A downstream end of a fourth inert gas supply pipe 249a is connected to the cleaning gas supply pipe 248a at the downstream side than the valve 248d. A fourth inert gas supply source 249b, an MFC 249c and a valve 249d are installed in the fourth inert gas supply pipe 249a sequentially from the upstream side.

A cleaning gas supply part is manly configured by the cleaning gas supply pipe 248a, the MFC 248c and the valve 248d. Furthermore, the cleaning gas source 248b, the fourth inert gas supply pipe 249a and the RPU 250 may be included in the cleaning gas supply part.

Furthermore, the inert gas supplied from the fourth inert gas supply source 249b may be supplied so as to act as a carrier gas or a dilution gas of the cleaning gas.

The cleaning gas supplied from the cleaning gas source 248b acts as a cleaning gas for removing byproducts adhering to the shower head 234 and the process chamber 201 at the cleaning step.

In the present embodiment, the cleaning gas is, for example, a nitrogen trifluoride (NF₃) gas. As the cleaning gas, it may be possible to use, for example, a hydrogen fluoride (HF) gas, a chlorine trifluoride (ClF₃) gas, a fluorine (F₂) gas, or a combination thereof.

A constitution having high responsiveness to a gas flow, such as a needle valve, an orifice or the like, may be used as the flow rate control part installed in each of the gas supply parts described above. For example, if a pulse width of a gas is of a millisecond order, there may be a case where an MFC cannot respond to a gas pulse. By combining a needle valve or an orifice with a high-speed on/off valve, it becomes possible to respond to a gas pulse of millisecond or less.

(Control Part)

As illustrated in FIGS. 1 and 5, the chamber 100 includes a controller 260 that controls the operations of the respective parts of the chamber 100.

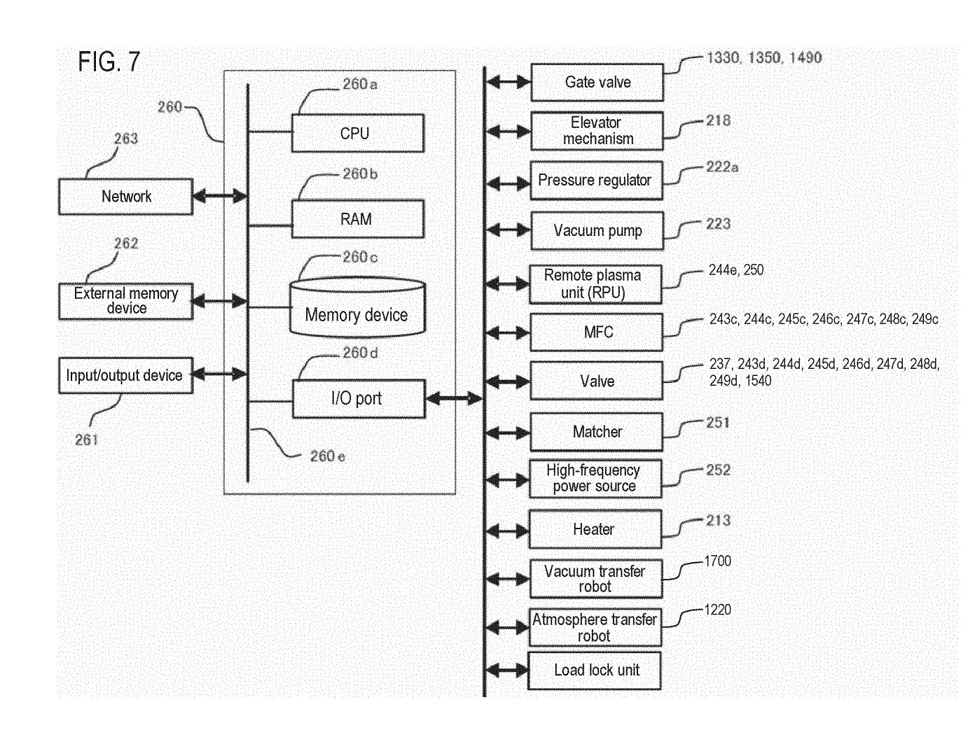

The outline of the controller 260 is illustrated in FIG. 7. The controller 260 serving as a control part (control means) is configured as a computer including a central processing unit (CPU) 260a, a random access memory (RAM) 260b, a memory device 260c and an I/O port 260d. The RAM 260b, the memory device 260c and the I/O port 260d are configured to exchange data with the CPU 260a via an internal bus 260e. An input/output device 261 configured as, e.g., a touch panel or the like, and an external memory device 262 are connectable to the controller 260.

The memory device 260c is configured by, for example, a flash memory, a hard disk drive (HDD), or the like. A control program for controlling the operations of the substrate processing apparatus, a process recipe in which a sequence, condition, or the like for the substrate processing described later is written, and the like are readably stored in the memory device 260c. In addition, the process recipe is a combination of sequences which causes the controller 260 to execute each sequence in a substrate processing process described later in order to obtain a predetermined result. The process recipe functions as a program. Hereinafter, the process recipe the control program, and the like will be generally and simply referred to as a program. Furthermore, the term “program” used herein may be intended to include the process recipe alone, the control program alone, or a combination of the process recipe and the control program. Moreover, the RAM 260b is configured as a memory area (work area) in which a program read by the CPU 260a, data, or the like are temporarily held.

The I/O port 260d is connected to the gate valves 1330, 1350 and 1490, the elevator mechanism 218, the heater 213, the pressure regulators 222a and 238, the vacuum pump 223, the matcher 251, the high-frequency power source 252, and so forth.

The CPU 260a is configured to read the control program from the memory device 260c and to execute the control program. Furthermore, the CPU 260a is configured to read the process recipe from the memory device 260c according to an operation command inputted from the input/output device 261 The CPU 260a is configured to, according to the read contents of the process recipe, control the opening/closing operations of the gate valves 1330, 1350, 1490(1490a, 1490b, 1490c, 1490d, 1490e, 1490f, 1490g and 1490h), the up/down operation of the elevator mechanism 218, the operation of supplying electric power to the heater 213, the pressure regulating operations of the pressure regulators 222a and 238, the on/off control of the vacuum pump 223, the gas activating operation of the remote plasma unit 244e, the on/off control of the valve 237, the electric power matching operation of the matcher 251, the on/off control of the high-frequency power source 252, and so forth.

In addition, the controller 260 is not limited to being configured as a dedicated computer but may be configured as a general-purpose computer. For example, the controller 260 according to the present embodiment may be configured by preparing the external memory device 262 (e.g., a magnetic tape, a magnetic disc such as a flexible disc or a hard disc, an optical disc such as a compact disc (CD) or a digital versatile disc (DVD), a magneto-optical disc such as MO, or a semiconductor memory such as a universal serial bus (USB) memory or a memory card) which stores the program described above, and installing the program on the general-purpose computer using the external memory device 262. Furthermore, a means for supplying the program to the computer is not limited to the case of supplying the program through the external memory device 262. For example, the program may be supplied using a communication means such as a network 263 (the Internet or a dedicated line) or the like without going through the external memory device 262. Moreover, the memory device 260c and the external memory device 262 are configured as a computer-readable recording medium. Hereinafter, these will be generally and simply referred to as a recording medium. Additionally, the term “recording medium” used herein may be intended to include the memory device 260c alone, the external memory device 262 alone, or both the memory device 260c and the external memory device 262.

(2) Substrate Processing Process

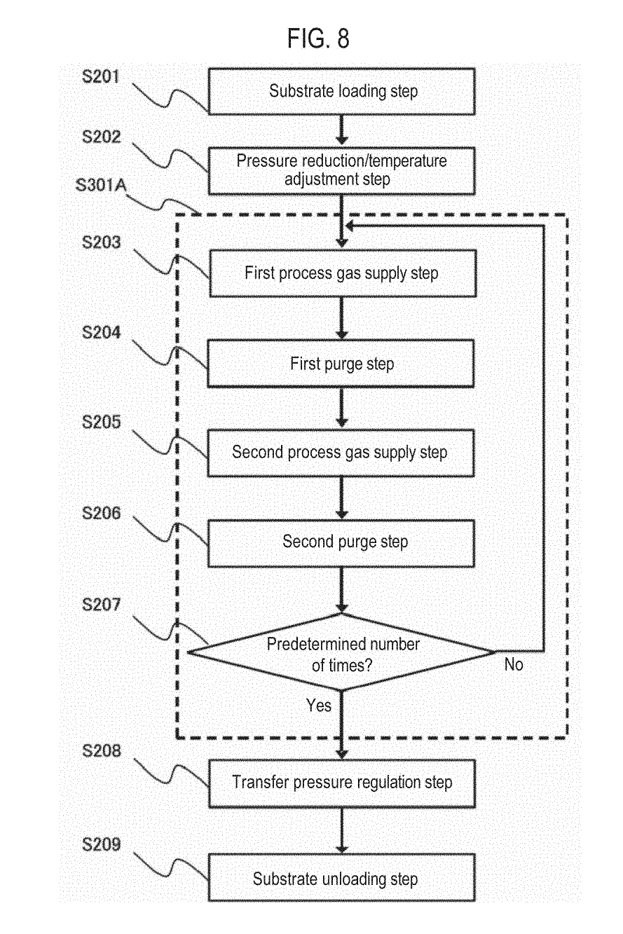

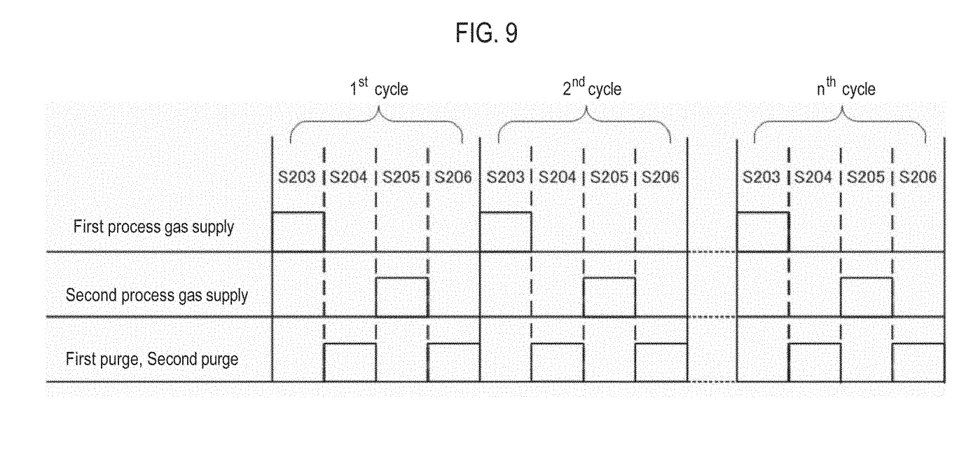

Next, as one of processes of manufacturing a semiconductor apparatus (semiconductor device) using the processing furnace of the substrate processing apparatus described above, a sequence example of forming an insulation film, for example, a silicon oxide (SiO) film as a silicon-containing film, on a substrate will be described with reference to FIGS. 8 and 9. In the following descriptions, the operations of the respective parts constituting the substrate processing apparatus are controlled by the controller 260.

As used herein, the term “wafer” may refer to “a wafer itself” or “a wafer and a laminated body (a collected body) of a wafer and predetermined layers or films formed on a surface of the wafer”. That is to say, a wafer including predetermined layers or films formed on its surface may be referred to as a wafer. In addition, as used herein, the phrase “a surface of a wafer” may refer to “a surface (exposed surface) of a wafer itself” or “a surface of a predetermined layer or film formed on a wafer, namely an uppermost surface of the wafer, which is a laminated body”.

Accordingly, as used herein, the expression “a predetermined gas is supplied to a wafer” may mean that “a predetermined gas is directly supplied to a surface (exposed surface) of a wafer itself” or that “a predetermined gas is supplied to a layer, a film, or the like formed on a wafer, namely on an uppermost surface of a wafer as a laminated body.” Furthermore, as used herein, the expression “a predetermined layer (or film) is formed on a wafer” may mean that “a predetermined layer (or film) is directly formed on a surface (exposed surface) of a wafer itself” or that “a predetermined layer (or film) is formed on a layer, a film, or the like formed on a wafer, namely on an uppermost surface of a wafer as a laminated body.”

In addition, the term “substrate” used herein may be synonymous with the term “wafer.” In this case, the term “wafer” and “substrate” may be used interchangeably in the foregoing descriptions.

Hereinafter, the substrate processing process will be described.

(Substrate Loading Step S201)

In the substrate processing process, the wafer 200 is first loaded into the process chamber 201. Specifically, the substrate support part 210 is moved down by the elevator mechanism 218 such that the lift pins 207 protrude from the through-holes 214 toward the upper surface side of the substrate support part 210. Furthermore, after the internal pressure of the process chamber 201 is regulated to a predetermined pressure, the gate valve 1490 is opened and the wafer 200 is mounted onto the lift pins 207 from the gate valve 1490. After the wafer 200 is mounted onto the lift pins 207, the substrate support part 210 is moved up to a predetermined position by the elevator mechanism 218 so that the wafer 200 is held on the substrate support part 210 from the lift pins 207.

(Pressure Reduction and Temperature Adjustment Step S202)

Subsequently, the interior of the process chamber 201 is evacuated through the exhaust pipe 224 such that the internal pressure of the process chamber 201 reaches a predetermined pressure (vacuum level). At this time, the opening degree of the APC valve as the pressure regulator 222a is feedback-controlled based on the pressure value measured by a pressure sensor. Furthermore, the amount of electric current supplied to the heater 213 is feedback-controlled based on the temperature value detected by a temperature sensor (not shown), such that the internal temperature of the process chamber 201 reaches a predetermined temperature. Specifically, the substrate support part 210 is preheated by the heater 213. After a temperature change in the wafer 200 or the substrate support part 210 disappears, the wafer 200 is left for a predetermined period of time. During this period, if degassing occurs from the moisture remaining in the process chamber 201 or the members existing in the process chamber 201, the gas may be removed by vacuum-exhausting or purging through the supply of a N₂ gas. By doing so, a preparation preceding a film forming process is completed. When evacuating the interior of the process chamber 201 to a predetermined pressure, the interior of the process chamber 201 may be evacuated at one time up to a reachable vacuum level.

(Film Forming Step S301A)

Next, descriptions will be made on an example where a SiO film is formed on the wafer 200. Details of the film forming step S301A will be described with reference to FIGS. 8 and 9.

After the wafer 200 is held on the substrate support part 210 and after the internal atmosphere of the process chamber 201 is stabilized, steps S203 to S207 illustrated in FIG. 8 are performed.

(First Gas Supply Step S203)

At a first gas supply step S203, a silicon-containing gas as a first gas (precursor gas) is supplied from the first gas supply part into the process chamber 201. As the silicon-containing gas, it may be possible to use, for example, a dichlorosilane (DCS) gas. Specifically, the gas valve is opened and the silicon-containing gas is supplied from the gas source into the substrate processing apparatus 100. At this time, the process chamber side valve is opened and the flow rate of the silicon-containing gas is adjusted to a predetermined flow rate by the MFC. The flow-rate-adjusted silicon-containing gas passes through the buffer space 232 and is supplied from the dispersion holes 234a of the shower head 234 into the process chamber 201 kept in a depressurized state. Furthermore, the evacuation of the interior of the process chamber 201 is performed by the exhaust system, thereby controlling the internal pressure of the process chamber 201 so as to become a pressure which falls within a predetermined range (first pressure). At this time, the silicon-containing gas to be supplied to the wafer 200 is supplied into the process chamber 201 at a predetermined pressure (a first pressure of, e.g., 100 Pa or more and 20,000 Pa or less). In this way, the silicon-containing gas is supplied to the wafer 200. By supplying the silicon-containing gas, a silicon-containing layer is formed on the wafer 200.

(First Purge Step S204)

After the silicon-containing layer is formed on the wafer 200, the supply of the silicon-containing gas is stopped. After stopping the supply of the precursor gas, a first purge step S204 is performed to exhaust the precursor gas existing in the process chamber 201 or the precursor gas existing in the buffer space 232, from the process chamber exhaust pipe 224.

At the first purge step, instead of discharging the gas by merely performing exhaust (vacuum drawing), the gas may be discharged by supplying an inert gas and pushing out the remaining gas. Furthermore, the vacuum drawing and the supply of the inert gas may be used in combination. Moreover, the vacuum drawing and the supply of the inert gas may be alternately performed.

At this time, the valve 237 of the shower head exhaust pipe 236 may be opened and the gas existing within the buffer space 232 may be exhausted from the shower head exhaust pipe 236. Furthermore, during the exhaust, the internal pressure (exhaust conductance) of the shower head exhaust pipe 236 and the buffer space 232 is controlled by the pressure regulator 222a and the valve 237. In this case, the pressure regulator 222a and the valve 237 may be controlled so that the exhaust conductance from the shower head exhaust pipe 236 in the buffer space 232 becomes higher than the exhaust conductance to the process chamber exhaust pipe 224 via the process chamber 201. By virtue of this adjustment, there is formed a gas flow which moves from the gas introduction hole 241, one end of the buffer space 232, to the shower head exhaust hole 240, the other end of the buffer space 232. By doing so, the gas adhering to the wall of the buffer space 232 or the gas floating within the buffer space 232 is exhausted from the shower head exhaust pipe 236 without entering the process chamber 201. Furthermore, the internal pressure of the buffer space 232 and the internal pressure (exhaust conductance) of the process chamber 201 may be adjusted so as to prevent backflow of the gas from the process chamber 201 into the buffer space 232.

Furthermore, at the first purge step, the vacuum pump 223 is continuously operated so that the gas existing within the process chamber 201 can be exhausted by the vacuum pump 223. Moreover, the pressure regulator 222a and the valve 237 may be adjusted so that the exhaust conductance from the process chamber 201 to the process chamber exhaust pipe 224 becomes higher than the exhaust conductance to the buffer space 232. By virtue of this adjustment, there is formed a gas flow which moves toward the process chamber exhaust pipe 224 via the process chamber 201. This makes it possible to exhaust the gas remaining within the process chamber 201.

After a predetermined period of time is elapsed, the supply of the inert gas is stopped and the valve 237 is closed, thereby cutting off the flow path which extends from the buffer space 232 to the shower head exhaust pipe 236.

More specifically, after a predetermined period of time is elapsed, the valve 237 may be closed while continuously operating the vacuum pump 223. By doing so, the gas flow moving toward the process chamber exhaust pipe 224 via the process chamber 201 is not affected by the shower head exhaust pipe 236. It is therefore possible to reliably supply the inert gas onto the substrate and to further improve the removal efficiency of the gas remaining on the substrate.

The act of purging the atmosphere of the process chamber means not only the act of discharging the gas by merely vacuum-drawing the process chamber but also the act of pushing out the gas by supplying the inert gas. Accordingly, at the first purge step, the discharge act may be performed by supplying the inert gas into the buffer space 232 and pushing out the remaining gas. Furthermore, the vacuum drawing and the supply of the inert gas may be used in combination. In addition, the vacuum drawing and the supply of the inert gas may be alternately performed.

In this case, the flow rate of the N₂ gas supplied into the process chamber 201 need not be made large. For example, the N₂ gas may be supplied in an amount substantially equal to the volume of the process chamber 201. By performing the purge in this way, it is possible to reduce the influence on the next step. Furthermore, by not completely purging the interior of the process chamber 201, it is possible to shorten the purge time and to improve the manufacturing throughput. Furthermore, it is possible to reduce the consumption of the N₂ gas to a necessary minimum level.

In this case, similar to the case of supplying the precursor gas to the wafer 200, the temperature of the heater 213 is set at a constant temperature which falls within a range of 200 to 750 degrees C., specifically 300 to 600 degrees C., more specifically 300 to 550 degrees C. The supply flow rate of the N₂ gas as the purge gas supplied from the respective inert gas supply systems is set at a flow rate which falls within a range of, for example, 100 to 20,000 sccm. As the purge gas, in addition to the N₂ gas, it may be possible to use a rare gas such as Ar, He, Ne, Xe or the like.

(Second Process Gas Supply Step S205)

After the first purge step, a nitrogen-containing gas as a second gas (reaction gas) is supplied into the process chamber 201 via the gas introduction hole 241 and the dispersion holes 234a. There is illustrated an example where an ammonia (NH₃) gas is used as the nitrogen-containing gas. Since the nitrogen-containing gas is supplied into the process chamber 201 via the dispersion holes 234a, it is possible to uniformly supply the nitrogen-containing gas onto the substrate. Thus, the film thickness can be made uniform. When supplying the second gas, an activated second gas may be supplied into the process chamber 201 via a remote plasma unit (RPU) as an activation part (excitation part).

In this case, the mass flow controller is adjusted so that the flow rate of the NH₃ gas becomes a predetermined flow rate. The supply flow rate of the NH₃ gas is, for example, 100 sccm or more and 10,000 sccm or less. When the NH₃ gas flows through the RPU, it is controlled such that the NH₃ gas is activated (excited) by keeping the RPU in an on-state (power supply state).

If the NH₃ gas is supplied to the silicon-containing layer formed on the wafer 200, the silicon-containing layer is modified. For example, a modified layer containing a silicon element is formed. Furthermore, a modified layer having an increased thickness can be formed by installing an RPU and supplying an activated NH₃ gas onto the wafer 200.

Depending on, for example, the internal pressure of the process chamber 201, the flow rate of the NH₃ gas, the temperature of the wafer 200 and the power supply state of the RPU, the modified layer is formed to have a predetermined thickness, a predetermined distribution and a predetermined depth of infiltration of a nitrogen component into the silicon-containing layer.

After a predetermined period of time is elapsed, the supply of the NH₃ gas is stopped.

(Second Purge Step S206)

After stopping the supply of the NH₃ gas, a second purge step S206 is performed to exhaust the NH₃ gas existing in the process chamber 201 or the NH₃ gas existing in the buffer space 232, from the first exhaust part. The second purge step S206 is similar to the first purge step S204 described above.

At the second purge step S206, the vacuum pump 223 is continuously operated so that the gas existing within the process chamber 201 can be exhausted from the process chamber exhaust pipe 224. Moreover, the pressure regulator 222a and the valve 237 may be adjusted so that the exhaust conductance from the process chamber 201 to the process chamber exhaust pipe 224 becomes higher than the exhaust conductance to the buffer space 232. By virtue of this adjustment, there is formed a gas flow which moves toward the process chamber exhaust pipe 224 via the process chamber 201. This makes it possible to exhaust the gas remaining within the process chamber 201. In this case, an inert gas is supplied. It is therefore possible to reliably supply the inert gas onto the substrate and to enhance the removal efficiency of the gas remaining on the substrate.

After a predetermined period of time is elapsed, the supply of the inert gas is stopped and the valve 237 is closed, thereby cutting off the flow path between the buffer space 232 and the shower head exhaust pipe 236.

More specifically, after a predetermined period of time is elapsed, the valve 237 may be closed while continuously operating the vacuum pump 223. By doing so, the gas flow moving toward the shower head exhaust pipe 236 via the process chamber 201 is not affected by the process chamber exhaust pipe 224. It is therefore possible to reliably supply the inert gas onto the substrate and to further improve the removal efficiency of the gas remaining on the substrate.

The act of purging the atmosphere of the process chamber means not only the act of discharging the gas by merely vacuum-drawing the process chamber but also the act of pushing out the gas by supplying the inert gas. Furthermore, the vacuum drawing and the supply of the inert gas may be used in combination. In addition, the vacuum drawing and the supply of the inert gas may be alternately performed.

In this case, the flow rate of the N₂ gas supplied into the process chamber 201 need not be made large. For example, the N₂ gas may be supplied in an amount substantially equal to the volume of the process chamber 201. By performing the purge in this way, it is possible to reduce the influence on the next step. Furthermore, by not completely purging the interior of the process chamber 201, it is possible to shorten the purge time and to improve the manufacturing throughput. Furthermore, it is possible to reduce the consumption of the N₂ gas to a necessary minimum level.

In this case, similar to the case of supplying the precursor gas to the wafer 200, the temperature of the heater 213 is set at a constant temperature which falls within a range of 200 to 750 degrees C., specifically 300 to 600 degrees C., more specifically 300 to 550 degrees C. The supply flow rate of the N₂ gas as the purge gas supplied from the respective inert gas supply systems is set at a flow rate which falls within a range of, for example, 100 to 20,000 sccm. As the purge gas, in addition to the N₂ gas, it may be possible to use a rare gas such as Ar, He, Ne, Xe or the like.

(Determination Step S207)

After the first purge step S206 is completed, the controller 260 determines whether the steps S203 to S206 of the film forming step S301A are performed a predetermined number of cycles n (where n is a natural number). That is to say, the controller 260 determines whether a film having a desired or specified thickness is formed on the wafer 200. By performing one cycle of the steps S203 to S206 at least once (step S207), an insulation film containing silicon and oxygen, namely a SiO film, which has a predetermined film thickness, can be formed on the wafer 200. The aforementioned cycle may be repeated multiple times. Thus, a SiO film having a predetermined film thickness is formed on the wafer 200.

If the cycle is not performed a predetermined number of times (if No at S207), the cycle of steps S203 to S206 is repeated. If the cycle of the steps S203 to S206 is performed a predetermined number of times (if Yes at S207), the film forming step S301A is completed. Then, a transfer pressure regulation step S208 and a substrate unloading step S209 are performed.

(Transfer Pressure Regulation Step)

At the transfer pressure regulation step S208, the interior of the process chamber 201 or the interior of the transfer space 203 is evacuated via the process chamber exhaust pipe 224 so that the internal pressure of the process chamber 201 or the internal pressure of the transfer space 203 becomes a predetermined pressure (vacuum level). At this time, the internal pressure of the process chamber 201 or the internal pressure of the transfer space 203 is regulated to become equal to or higher than the internal pressure of the vacuum transfer chamber 1400. During, before or after the transfer pressure regulation step S208, the wafer 200 may be held on the lift pins 207 so that the temperature of the wafer 200 is reduced to a predetermined temperature.

(Substrate Unloading Step S209)

After the internal pressure of the process chamber 201 is regulated to a predetermined temperature at the transfer pressure regulation step S208, the gate valve 1490 is opened and the wafer 200 is unloaded from the transfer space 203 to the vacuum transfer chamber 1400.

The processing of the wafer 200 is performed through the aforementioned steps.

### Other Embodiments

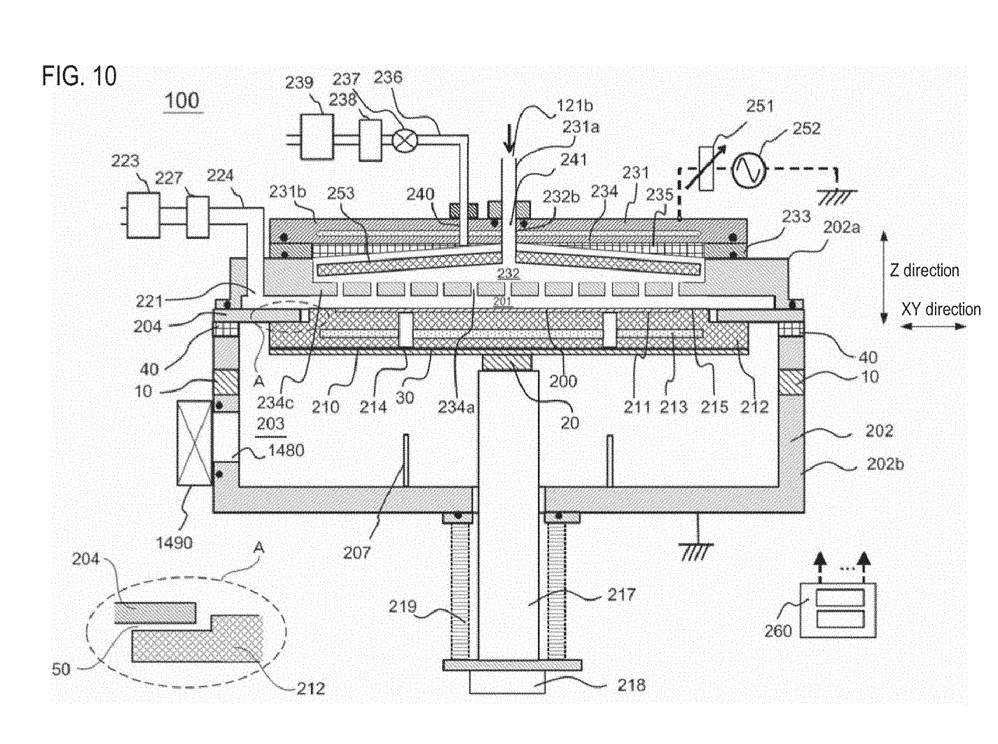

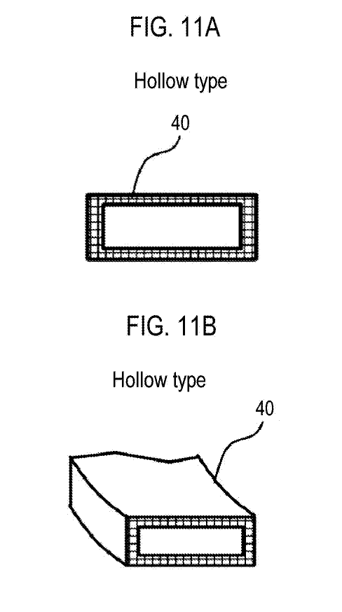

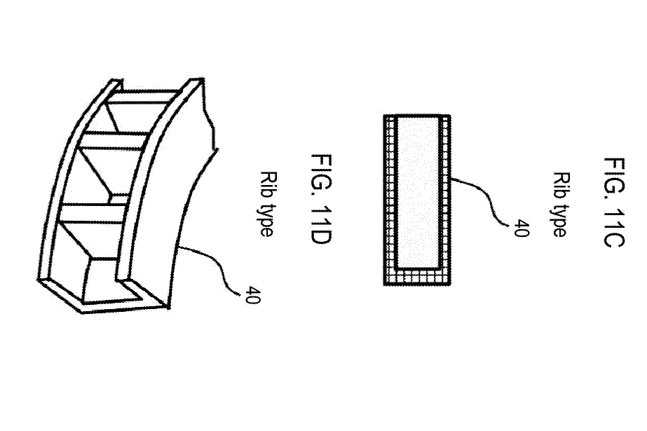

FIGS. 10 and 11 illustrate other embodiments. When the wafer 200 is thermally processed in the substrate processing apparatus 100, the interior of the process vessel 202 is exposed to a high temperature. Thus, the process vessel 202 (the upper vessel 202a and the lower vessel 202b) is expanded in the XY direction and the Z direction in FIG. 10. The present inventors have found that a variety of problems is generated due to this expansion. The X direction and the Y direction referred to herein are the directions parallel to the surface of through wafer 200 and are the same as the directions illustrated in FIG. 1. The Z direction is the direction perpendicular to the surface of the wafer 200.

For example, the lower vessel 202b is expanded in the Z direction. Thus, the distance between the substrate mounting stand 212 and the shower head 234 (height of the buffer space 232) is changed and the conductance within the process chamber 201 is changed. Consequently, the processing uniformity is reduced. Furthermore, due to the expansion of the lower vessel 202b in the Z direction, a gap 50 is formed between the substrate mounting stand 212 and the partition plate 204 (see round dot line A in FIG. 10). As a result, the gas supplied into the process chamber 201 or the byproduct generated in the process chamber 201 may enter the transfer chamber 203. Due to the entry of the gas or the byproduct into the transfer chamber 203, films or particles may adhere to the members existing within the transfer chamber 203. The members referred to herein are, for example, the inner wall of the transfer chamber 203, the rear surface of the substrate mounting stand 212, the lift pins 207, the shaft 217, the bellows 219, the gate valve 1490, and so forth. The films or particles may flow from the transfer chamber 203 into the process chamber 201 at the substrate loading step S201, the first purge step S204, the second purge step S206 and the substrate unloading step S209, thereby hindering the processing of the wafer 200 and deteriorating the flatness of a film formed on the wafer 200.

Furthermore, for example, the lower vessel 202b is expanded in one or both of the X direction and the Y direction. Thus, the center of the substrate mounting stand 212 and the center of the shower head 234 may be out of alignment and the processing uniformity of the wafer 200 may be deteriorated. Moreover, the present inventors have found that due to the misalignment of the upper vessel 202a and the lower vessel 202b in the XY direction, a stress may be applied to the connection portion of the upper vessel 202a and the lower vessel 202b and one or both of the upper vessel 202a and the lower vessel 202b may be broken.

The present inventors have conducted extensive studies in order to solve the aforementioned problems. As a result, the present inventors have found that, by installing a stress relaxation material between the upper vessel 202a and the lower vessel 202b, it is possible to absorb the Z direction expansion of the upper vessel 202a and the Z direction expansion of the lower vessel 202b and to absorb the misalignment of the upper vessel 202a and the lower vessel 202b in one or both of the X direction and the Y direction.

FIG. 10 illustrates an example in which a stress relaxation material 40 is installed above the first thermal insulation part 10. FIGS. 11A to 11D illustrate a hollow-type stress relaxation material and a rib-type stress relaxation material as examples of the stress relaxation material 40. The stress relaxation material 40 restrains the center positions of the substrate mounting stand 212 and the shower head 234 from being misaligned by the expansion of the process vessel 202 attributable to the influence of heat generated from the heater 213. The positions of the first thermal insulation part 10 and the stress relaxation material 40 may be reversed in the up-down direction. As one example of the stress relaxation material 40, FIG. 11A illustrates a cross-sectional view of a hollow-type stress relaxation material 40 and FIG. 11B illustrates a perspective view thereof. A coolant may be caused to flow through the hollow-type stress relaxation material 40. FIG. 11C illustrates a cross-sectional view of a rib-type stress relaxation material 40 and FIG. 11D illustrates a perspective view thereof. By employing the rib-type (fin-type) stress relaxation material 40, it is possible to cool the stress relaxation material 40. In the present embodiment, the first thermal insulation part 10 and the stress relaxation material 40 have been described as being independent bodies. However, the first thermal insulation part 10 and the stress relaxation material 40 may be formed into one piece. The thermal insulation part may be formed in the shape of the stress relaxation material 40.

By forming the stress relaxation material 40 in the hollow-type structure illustrated in FIGS. 11A and 11B or in the rib-type structure illustrated in FIGS. 11C and 11D, the cross-sectional area of the first thermal insulation part 10 in the direction parallel to the substrate 200 can be set to become smaller than the cross-sectional area of the wall of the transfer chamber 203 in the direction parallel to the substrate 200. By setting the cross-sectional area of the first thermal insulation part 10 smaller than the cross-sectional area of the wall of the transfer chamber 203, it is possible to reduce the amount of heat transferred from the process chamber 201 to the wall of the transfer chamber 203.

In the foregoing descriptions, there has been illustrated the example where the second thermal insulation part 20 has a length equal to the diameter of the shaft 217. However, the present disclosure is not limited thereto. As illustrated in FIG. 10 the length of the second thermal insulation part 20 may be set smaller than the diameter of the shaft 217. By setting the length of the second thermal insulation part 20 smaller than the diameter of the shaft 217 in this way, it is possible to reduce the amount of heat transferred from the substrate mounting stand 212 to the shaft 217. Furthermore, by reducing the surface area of the second thermal insulation part 20, it is possible to suppress heat radiation from the second thermal insulation part 20 to the members existing within the transfer chamber 203. Furthermore, the second thermal insulation part 20 may be a hollow structure or a rib structure illustrated in FIGS. 11A to 11D. This makes it possible to reduce the amount of heat transferred from the substrate mounting stand 212 to the shaft 217.

In the foregoing descriptions, there has been illustrated the method of forming the film by alternately supplying a precursor gas and a reaction gas. However, the present disclosure may be applied to other methods as long as a gas phase reaction amount of the precursor gas and the reaction gas or a generation amount of the byproduct falls within a permissible range. For example, it may be possible to use a method in which the supply timings of a precursor gas and a reaction gas overlap with each other.

In the foregoing descriptions, there has been illustrated the film forming process. However, the present disclosure may be applied to other processes, for example, a diffusion process, an oxidation process, a nitriding process, an oxynitriding process, a reduction process, an oxidation/reduction process, an etching process and a heating process. For example, the present disclosure may be applied to a case where a substrate surface or a film formed on a substrate is subjected to a plasma oxidation process or a plasma nitriding process using only a reaction gas. Furthermore, the present disclosure may be applied to a plasma annealing process using only a reaction gas.

In the foregoing descriptions, there has been illustrated the semiconductor apparatus manufacturing process. However, the present disclosure may be applied to processes other than the semiconductor apparatus manufacturing process, for example, substrate processing processes such as a liquid crystal device manufacturing process, a solar cell manufacturing process, a light emitting device manufacturing process, a glass substrate processing process, a ceramic substrate processing process and a conductive substrate processing process.

In the foregoing descriptions, there has been illustrated the example where the silicon oxide film is formed using the silicon-containing gas as the precursor gas and using the nitrogen-containing gas as the reaction gas. However, the present disclosure may be applied to film formation using other gases. For example, the present disclosure may be applied to formation of an oxygen-containing film, a nitrogen-containing film, a carbon-containing film, a boron-containing film, a metal-containing film or a film containing these elements. Examples of these films may include a SiN film, an AlO film, a ZrO film, an HfO film, a HfAlO film, a ZrAlO film, a SiC film, a SiCN film, a SiBN film, a TiN film, a TiC film and a TiAlC film. Similar effects can be achieved by appropriately changing the supply position and the internal structure of the shower head 234 in view of the gas properties (an adsorption property, a desorption property, a vapor pressure, etc.) of a precursor gas and a reaction gas used in forming these films.

One chamber or a plurality of chambers may be installed within the process module. In the case of installing a plurality of chambers within the process module, the thermal capacity of the process module grows larger. This may largely affect the maintenance of one or more process modules.

In the foregoing descriptions, there has been illustrated the apparatus configuration in which one substrate is processed in one process chamber. However, the present disclosure is not limited thereto but may be applied to an apparatus in which a plurality of substrates are horizontally or vertically arranged.

According to the present disclosure in some embodiments, it is possible to improve the processing uniformity.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A substrate processing apparatus, comprising:
a process vessel comprising an upper vessel forming a process space configured to process a substrate and a lower vessel forming a transfer space adjoining the process space;
a shaft installed in the transfer space;
a substrate mounting stand connected to the shaft and including a heating part, the substrate mounting stand configured to be movable between a processing position and a transfer position;
a partition plate installed onto a sidewall of the lower vessel and positioned on and in contact with an upper periphery of the substrate mounting stand, when the substrate mounting stand is positioned in the processing position, such that the upper vessel and the lower vessel are partitioned from each other by the substrate mounting stand and the partition plate;
a first thermal insulation part installed in a wall of the lower vessel surrounding the transfer space, being biased toward the upper vessel, below the partition plate so as to surround the transfer space; and
a second thermal insulation part installed higher than a position of the first thermal insulation part between the shaft and the substrate mounting stand, when the substrate mounting stand is positioned in the processing position to restrain heat generated in the process space from being transferred to the shaft.

2. (canceled)

3. The apparatus of claim 1, wherein the first thermal insulation part is installed higher than a height of a gate valve installed in the wall of the lower vessel, and
the second thermal insulation part is installed in a position where, when performing a process, the second thermal insulation part is kept higher than the height of the gate valve.

4. (canceled)

5. The apparatus of claim 1, further comprising:
a reflection part disposed between the second thermal insulation part and the substrate mounting stand,
wherein a lateral surface of the second thermal insulation part is exposed to the transfer space.

6. (canceled)

7. The apparatus of claim 3, further comprising:
a reflection part disposed between the second thermal insulation part and the heating part.

8. The apparatus of claim 1, wherein a cross-sectional area of the first thermal insulation part in a direction parallel to the substrate is set smaller than a cross-sectional area of the wall of the lower vessel in a direction parallel to the substrate.

9. (canceled)

10. The apparatus of claim 3, wherein a cross-sectional area of the first thermal insulation part in a direction parallel to the substrate is set smaller than a cross-sectional area of the wall of the lower vessel in a direction parallel to the substrate.

11. The apparatus of claim 7, wherein a cross-sectional area of the first thermal insulation part in a direction parallel to the substrate is set smaller than a cross-sectional area of the wall of the lower vessel in a direction parallel to the substrate.

12. The apparatus of claim 1, wherein the first thermal insulation part has one of a hollow structure and a structure having a plurality of fins disposed along a circumferential direction of the substrate mounting stand at an outer side of the lower vessel.

13. (canceled)

14. The apparatus of claim 3, wherein the first thermal insulation part has one of structures including a hollow structure and a structure having a plurality of fins disposed along a circumferential direction of the substrate mounting stand at an outer side of the lower vessel.

15. The apparatus of claim 5, wherein the first thermal insulation part has one of structures including a hollow structure and a structure having a plurality of fins disposed along a circumferential direction of the substrate mounting stand at an outer side of the lower vessel.

16. The apparatus of claim 8, wherein the first thermal insulation part has one of structures including a hollow structure and a structure having a plurality of fins disposed along a circumferential direction of the substrate mounting stand at an outer side of the lower vessel.

17. The apparatus of claim 11, wherein the first thermal insulation part has one of structures including a hollow structure and a structure having a plurality of fins disposed along a circumferential direction of the substrate mounting stand at an outer side of the lower vessel.

18. The apparatus of claim 1, wherein a stress relaxation material is installed between the upper vessel and the lower vessel.
